(19) United States
(12) Patent Application Publication
(10) Pub. No.: US 2024/0381729 A1
(43) Pub. Date: Nov. 14, 2024

(54) DISPLAY PANEL AND DEPOSITION APPARATUS

(71) Applicant: Samsung Display Co., Ltd., Yongin-si (KR)

(72) Inventors: SEUNGJIN LEE, Yongin-si (KR); SANGSHIN LEE, Yongin-si (KR); SANGHOON KIM, Yongin-si (KR)

(21) Appl. No.: 18/408,399

(22) Filed: Jan. 9, 2024

(30) Foreign Application Priority Data
May 12, 2023 (KR) 10-2023-0061630

(51) Int. Cl. H10K 59/35; C23C 14/04; H10K 71/16

(52) U.S. Cl. CPC H10K 59/353; C23C 14/042; H10K 59/352; H10K 71/166

(57) ABSTRACT

A display panel includes: a plurality of first display regions arranged along a first direction; a second display region between the first display regions; a first pixel in each of the first display regions; and a second pixel in the second display region. Each of the first pixel and the second pixel includes: a first color emission element; a second color emission element spaced apart from the first color emission element in the first direction; and a third color emission element spaced apart from the first color emission element in the first direction and from the second color emission element in a second direction. The second direction crosses the first direction. A shape of an emission region of the second color emission element in the first pixel is different from a shape of an emission region of the second color emission element in the second pixel.

### CROSS-REFERENCE TO RELATED APPLICATION

The present application claims priority to and the benefit of Korean Patent Application No. 10-2023-0061630, filed on May 12, 2023, in the Korean Intellectual Property Office, the entire disclosure of which is incorporated herein by reference.

### BACKGROUND

### 1. Field

Aspects of embodiments of the present disclosure relates to a display panel and a deposition apparatus.

### 2. Description of the Related Art

Generally, a light-emitting display panel includes an emission element disposed for each pixel. The emission element includes an emission layer disposed between two electrodes. The emission layers disposed for each pixel may be divided into a plurality of groups.

A plurality of mask assemblies are used to deposit the plurality of groups of emission layers on a work substrate. Each of the mask assemblies includes a frame and a mask. After the work substrate is placed on the mask, light-emitting materials may be deposited on the work substrate to form a pattern of the emission layers.

### SUMMARY

An embodiment of the present disclosure provides a display panel that prevents the occurrence of a difference in recognition between neighboring pixel regions.

An embodiment of the present disclosure provides a deposition apparatus for fabricating a display panel that prevents the occurrence of a difference in recognition between neighboring pixel regions.

A display panel, according to an embodiment of the present disclosure, includes: a plurality of first display regions arranged along a first direction; a second display region between the first display regions; a first pixel in each of the first display regions; and a second pixel in the second display region. Each of the first pixel and the second pixel includes: a first color emission element; a second color emission element spaced apart from the first color emission element in the first direction; and a third color emission element spaced apart from the first color emission element in the first direction and from the second color emission element in a second direction. The second direction crosses the first direction, and a shape of an emission region of the second color emission element in the first pixel is different from a shape of an emission region of the second color emission element in the second pixel.

A shape of an emission region of the third color emission element in the first pixel may be different from a shape of an emission region of the third color emission element in the second pixel.

A shape of an emission region of the first color emission element in the first pixel may be different from a shape of an emission region of the first color emission element in the second pixel.

An area of the emission region of the first color emission element in the first pixel may be substantially the same as an area of the emission region of the first color emission element in the second pixel.

Each of the first pixel and the second pixel may be provided in plural, and the second color emission elements of the second pixels and the third color emission elements of the second pixels may be alternately arranged along the second direction.

The second color emission elements of the first pixels and the third color emission elements of the first pixels may be alternately arranged along the second direction.

The first pixel and the second pixel may be aligned along the first direction or the second direction.

The emission region of the second color emission element in the second pixel may have a first triangular shape in a plan view that is line-symmetric about a direction parallel to the first direction, and an emission region of the third color emission element in the second pixel may have a second triangular shape in a plan view that is line-symmetric about the direction parallel to the first direction.

An emission region of the first color emission element in the second pixel may have a rectangular shape in a plan view, one side of the first triangular shape and one end of the second triangular shape may face one side of the rectangular shape, and the one side of the first triangular shape and one side of the second triangular shape may extend in the same direction.

Each of the first pixel and the second pixel may be provided in plural, the first triangular shapes of neighboring ones of the second pixels may be line-symmetric about the direction parallel to the first direction, and the second triangular shapes of neighboring ones of the second pixels may be line-symmetric about the direction parallel to the first direction.

Each of the first pixel and the second pixel may be provided in plural. The emission region of the second color emission element in each of the second pixels may have a first polygonal shape in a plan view, an emission region of the third color emission element in each of the first pixels may have a second polygonal shape in a plan view. The first polygonal shape of each of the second pixels may be line-symmetric about a direction parallel to the first direction, and the second polygonal shape of each of the first pixels may be line-symmetric about the direction parallel to the first direction.

Emission regions of the first, second, and third color emission elements may have different areas from each other.

A width of each of the first display regions in the first direction may be greater than a width of the second display region in the first direction.

A deposition apparatus, according to an embodiment of the present disclosure, includes: a deposition source configured to provide a substrate with a deposition material; and a plurality of mask assemblies between the deposition source and the substrate. The plurality of mask assemblies includes a first mask assembly including: a first frame having a first frame opening that penetrates the first frame along a thickness direction of the first frame; a first mask connected to the first frame and having a plurality of first openings, each of which overlaps the first frame opening in a plan view; and a second mask connected to the first frame and spaced apart from the first mask in a first direction and having a plurality of second openings, each of which overlaps the first frame opening in a plan view and has the same shape as the first opening. A plurality of first sub-openings are defined between the first mask and the second mask, and the first sub-opening has a shape different from the shape of the first opening and the second opening.

The plurality of mask assemblies may further include a second mask assembly including: a second frame having a second frame opening that penetrates the second frame along a thickness direction of the second frame; a third mask connected to the second frame and having a plurality of third openings, each of which overlaps the second frame opening in a plan view; and a fourth mask connected to the second frame and spaced apart from the third mask in the first direction and having a plurality of fourth openings, each of which overlaps the second frame opening in a plan view. The second mask assembly may be configured to replace the first mask assembly on the substrate, and a plurality of second sub-openings may be defined between the third mask and the fourth mask. The second sub-opening may have a shape different from the third opening and the fourth opening.

The first mask may have a first surface that extends along a second direction crossing the first direction, the second mask may have a second surface that extends along the second direction and faces the first surface and a plurality of first protrusions protruding from the second surface toward the first mask, and the first sub-openings may be defined between the first protrusions and the first surface.

The first protrusion may have a first inclined surface that is oblique at a first angle with respect to the second surface and a second inclined surface that is oblique at a second angle with respect to the first surface.

The first angle and the second angle may be the same.

The third mask may have a third surface that extends along the second direction and a plurality of second protrusions protruding from the third surface toward the fourth mask, the fourth mask may have a fourth surface that extends along the second direction and faces the third surface, and the second sub-openings may be defined between the second protrusions and the third surface.

The plurality of first protrusions may be spaced apart from each other at a first interval along the second direction, and the plurality of second protrusions may be spaced apart from each other at a second interval along the second direction.

### BRIEF DESCRIPTION OF DRAWINGS

FIG. 1 is a plan view of a display panel according to an embodiment of the present disclosure.

FIG. 2A is an enlarged plan view of the portion AA of FIG. 1 according to an embodiment of the present disclosure.

FIG. 2B is a plan view of a first pixel region and a second pixel region shown in FIG. 2A.

FIG. 3A is an enlarged plan view of the portion AA of FIG. 1 according to another embodiment of the present disclosure.

FIG. 3B is a plan view of a first pixel region and a second pixel region shown in FIG. 3A.

FIG. 4 is a cross-sectional view of a portion of a display panel according to an embodiment of the present disclosure.

FIG. 5 is a cross-sectional view of a deposition apparatus according to an embodiment of the present disclosure.

FIG. 6 is a perspective view of a mask assembly according to an embodiment of the present disclosure.

FIGS. 7A to 7C are plan views of mask assemblies according to an embodiment of the present disclosure.

FIGS. 8A and 8B are plan views of mask assemblies according to an embodiment of the present disclosure.

FIGS. 9 to 11 are plan views showing a state in which different mask assemblies overlap a portion of a work substrate according to an embodiment of the present disclosure.

### DETAILED DESCRIPTION

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Unless otherwise defined, all terms used herein including technical and scientific terms have the same meaning generally understood by one of ordinary skilled in the art. Also, terms as defined in generally used dictionaries should be understood as having meanings identical to or contextually defined in the art and should not be understood as ideally or excessively formal meaning unless definitely defined herein.

With reference to the accompanying drawings, the following will describe a display panel and a method of fabricating the same according to embodiments of the present disclosure.

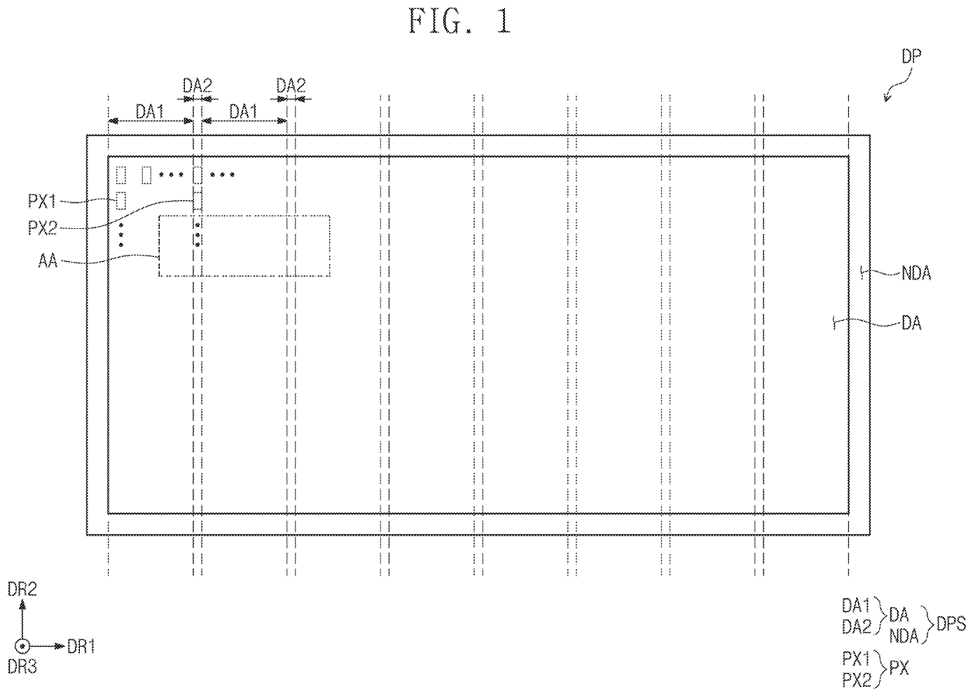

FIG. 1 is a plan view of a display panel DP according to an embodiment of the present disclosure.

The display panel DP depicted in FIG. 1 may be an emissive display panel, such as an inorganic light-emitting display panel or an organic light-emitting display panel, but the present disclosure is not limited thereto.

As shown in FIG. 1, the display panel DP may be parallel to a plane defined by a first directional axis DR1 and a second directional axis DR2. A third directional axis DR3 may indicate a normal direction of the display panel DP or a thickness direction of the display panel DP. The third directional axis DR3 may differentiate a front surface (or top surface) and a rear surface (or bottom surface) of each layer or unit discussed below. However, the first, second, and third directional axes DR1, DR2, and DR3 are illustratively shown in the present embodiment. In the following description, first, second, and directions may be directions indicated by the first, second, and third directional axes DR1, DR2, and DR3, respectively, and the same reference numerals may be allocated thereto.

The display panel DP may have a display surface DPS on which an image is displayed. The display surface DPS may have a display region DA and a non-display region NDA. A pixel PX may be disposed in the display region DA. For example, the display region DA may be a zone (or area) at where an image generated by the pixel PX is displayed. Thus, a region where light is displayed (or emitted) or an emission region of the pixel PX may be disposed in the display region DA.

The non-display region NDA may be adjacent to the display region DA. The non-display region NDA may be defined along an edge of (or a periphery of) the display panel DP. The non-display region NDA may surround (e.g., may extend around a periphery of) the display region DA. In an embodiment of the present disclosure, the non-display region NDA may be omitted or may be disposed on only one side or fewer than all sides of the display region DA.

The display region DA may include a first display region DA1 and a second display region DA2. The first display region DA1 and the second display region DA2 may be sections (or areas) having different widths defined along the first direction DR1.

A plurality of first pixels PX1 may be disposed in the first display region DA1. The first display region DA1 may be provided in plural. The plurality of first display regions DA1 may be arranged along (e.g., may be adjacent to each other in) the first direction DR1. The plurality of first display regions DA1 may be spaced apart from each other in the first direction DR1.

A plurality of second pixels PX2 may be disposed in the second display region DA2. The second pixels may have an emission region different from that of the first pixels PX1. A detailed description thereof will be provided below. The second display region DA2 may be disposed between two neighboring ones of the first display regions DA1. The second display region DA2 may be provided in plural. The plurality of first display regions DA1 and the plurality of second display regions DA2 may be alternately arranged along the first direction DR1.

Each of the first display regions DA1 may have a width defined in the first direction DR1 that is greater than a width defined in the first direction DR1 of the second display regions DA2 (e.g., the first display regions DA1 may be wider in the first direction DR1 than the second display region DA2). Each of the second display regions DA2 may correspond to (or may form) a boundary region between the first display regions DA1.

The display panel DP is illustrated in FIG. 1 as a panel with the display surface DPS having a flat rectangular shape with long side extending along the first direction DR1 and short side extending along the second direction DR2, but the present disclosure is not limited thereto. The display panel DP may have a curved display surface or a three-dimensional display surface. The three-dimensional display device may include a plurality of display regions oriented in (e.g., facing) different directions from each other. In another embodiment, the display panel DP may be a rigid display panel or a flexible display panel, such as a rollable display panel, a foldable display panel, or a slidable display panel. The display panel DP may be foldable or rollable while having flexible characteristics.

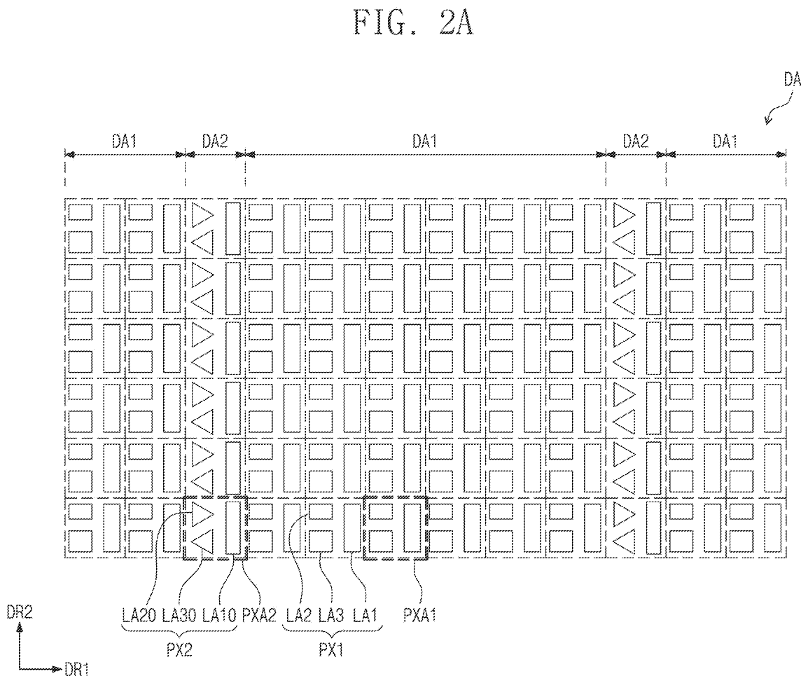

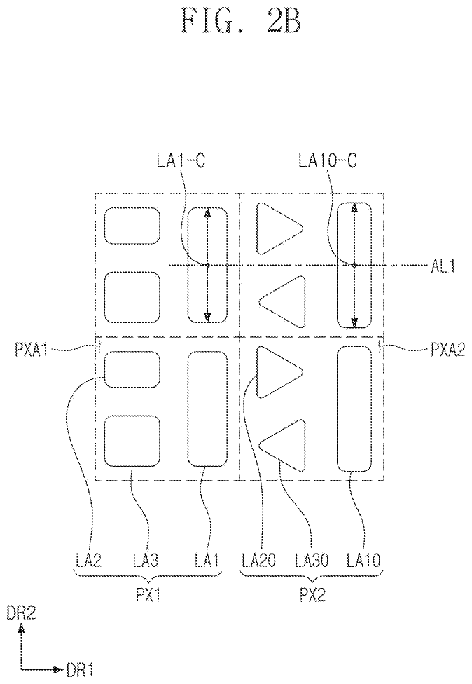

FIG. 2A is an enlarged plan view of a portion of a display panel according to an embodiment of the present disclosure. FIG. 2B is a plan view of a first pixel region and a second pixel region according to an embodiment of the present disclosure. In more detail, FIG. 2A is an enlarged plan view of the section AA of the display panel DP shown in FIG. 1, and FIG. 2B is a plan view of a first pixel region PXA1 and a second pixel region PXA2 shown in FIG. 2A.

Referring to FIG. 2A, the first display region DA1 may include a plurality of first pixel regions PXA1, and the second display region DA2 may include a plurality of second pixel regions PXA2. The first pixel PX1 may be disposed in every one of the plurality of first pixel regions PXA1, and the second pixel PX2 may be disposed in every one of the plurality of second display regions DA2.

The first pixel regions PXA1 and the second pixel regions PXA2 may have the same area as each other. The first pixel regions PXA1 may be imaginary regions obtained by dividing the first display region DA1 into segments having the same area, and the second pixel regions PXA2 may be imaginary regions obtained by dividing the second display region DA2 into segments having the same area.

The plurality of first pixels PX1 or the plurality of first pixel regions PXA1 may be arranged both in the first direction DR1 to constitute a plurality of pixel rows and in the second direction DR2 to constitute a plurality of pixel columns. The plurality of first pixels PX1 may be arranged in a matrix shape. For example, when the plurality of first pixels PX1 are provided in an n×m arrangement (where each of n and m is a natural number equal to or greater than 2), the plurality of first pixels PX1 may be arranged while forming n number of pixel rows and m number of pixel columns.

In contrast, the plurality of second pixels PX2 or the plurality of second pixel regions PXA2 may be arranged in the second direction DR2 to constitute a single pixel column. In one second display region DA2, the second pixels PX2 may be provided in k×1 number (where k is a natural number equal to or greater than 2) and may be arranged while forming a matrix of k rows and one column.

The plurality of first pixels PX1 and the plurality of second pixels PX2 may each include a first color sub-pixel, a second color sub-pixel, and a third color sub-pixel. In FIG. 2, emission regions LA1, LA2, LA3, LA10, LA20, and LA30 of the first color sub-pixel, the second color sub-pixel, and the third color sub-pixel are illustrated as representatives of the first color sub-pixel, the second color sub-pixel, and the third color sub-pixel. For example, the first pixel region PXA1 may include emission regions LA1, LA2, and LA3 (referred to hereinafter as first, second, and third emission regions of a first pixel) of sub-pixels that constitute the first pixel PX1, and the second pixel region PXA2 may include emission regions LA10, LA20, and LA30 (referred to hereinafter as first, second, and third emission regions of a second pixel) of sub-pixels that constitute the second pixel PX2. In the illustrated embodiment, the first, second, and third colors may be red, green, and blue, respectively, but the present disclosure is not limited thereto.

An arrangement of the emission regions LA1, LA2, LA3, LA10, LA20, and LA30 of the first color sub-pixel, the second color sub-pixel, and the third color sub-pixel may be the same as that of the first color sub-pixel, the second color sub-pixel, and the third color sub-pixel and may also be the same as that of emission elements of the first color sub-pixel, the second color sub-pixel, and the third color sub-pixel.

The first color sub-pixel, the second color sub-pixel, and the third color sub-pixel may be identically arranged in the first pixels PX1. The first color sub-pixel, the second color sub-pixel, and the third color sub-pixel may be identically arranged in the second pixels PX2.

An arrangement of a first color emission element LA1, a second color emission element LA2, and a third color emission element LA3 of the first pixel PX1 may be substantially the same as that of a first color emission element LA10, a second color emission element LA20, and a third color emission element LA30 of the second pixel PX2. For example, sub-pixels included in the first pixel PX1 and sub-pixels included in the second pixel PX2 may have different shapes of emission regions but may have the same arrangement. A shape of an emission region may be defined by a shape on a plane formed by the first direction DR1 and the second direction DR2, and an arrangement of emission regions may be defined by their positions on the plane.

According to the illustrated disclosure, an arrangement of the first, second, and third color emission elements LA1, LA2, and LA3 of the first pixel PX1 may be substantially the same as that of the first, second, and third color emission elements LA10, LA20, and LA30 of the second pixel PX2, and thus, it may be possible to prevent failure of recognition between corresponding emission regions of the first pixel PX1 and the second pixel PX2 between neighboring pixel regions (e.g., a visual difference between the emission regions of the first pixel PX1 and the second pixel PX2 may not be noticeable to a user).

For convenience of description, the first color emission elements LA1 and LA10 will each be illustrated corresponding to a first emission region, the second emission elements LA2 and LA20 will each be illustrated corresponding to a second emission region, and the third color emission elements LA3 and LA30 will each be illustrated corresponding to a third emission region.

The second emission region LA2 of the first pixel PX1 may be disposed spaced apart in the first direction DR1 from the first emission region LA1 of the first pixel PX1, and the third emission region LA3 of the first pixel PX1 may be disposed spaced apart in the first direction DR1 from the first emission region LA1 of the first pixel PX1. The third emission region LA3 of the first pixel PX1 may be disposed spaced apart in the second direction DR2 from the second emission region LA2 of the first pixel PX1.

As discussed above, the second pixel PX2 may have emission regions whose arrangement shape is the same as that of emission regions of the first pixel PX1. For example, the second emission region LA20 of the second pixel PX2 may be disposed spaced apart in the first direction DR1 from the first emission region LA10 of the second pixel PX2, and the third emission region LA30 of the second pixel PX2 may be disposed spaced apart in the first direction DR1 from the first emission region LA10 of the second pixel PX2. The third emission region LA30 of the second pixel PX2 may be disposed spaced apart in the second direction DR2 from the second emission region LA20 of the second pixel PX2.

The second emission regions LA2 of the first pixels PX1 and the third emission regions LA3 of the first pixels PX1 may be alternately arranged along the second direction DR2. The second emission regions LA20 of the second pixels PX2 and the third emission regions LA30 of the second pixels PX2 may be alternately arranged along the second direction DR2.

Referring to FIG. 2B, the first emission regions LA1 and LA10, the second emission region LA2, and the third emission region LA3 are illustrated as having rectangular shapes with curved vertices, and the second emission region LA20 and the third emission region LA30 are illustrated as having triangular shapes with curved vertices. The present disclosure is not limited thereto, and the emission regions LA1, LA10, LA2, LA20, LA3, and LA30 may have square shapes, rectangular shapes, or any other polygonal shapes in mathematical sense. For example, in the present disclosure, vertices of shapes that define emission regions not only by straight lines but also by curved lines.

According to an embodiment of the present disclosure, the first emission region LA1 of the first pixel PX1 may have a shape different from that of the first emission region LA10 of the second pixel PX2. For example, the first emission regions LA1 and LA10 may have different rectangular shapes from each other. The first emission region LA1 of the first pixel PX1 and the first emission region LA10 of the second pixel PX2 may each have a length in the first direction DR1 and a length in the second direction DR2, and the length in the first direction DR1 may be different from the length in the second direction DR2.

According to an embodiment of the present disclosure, the second emission region LA2 of the first pixel PX1 may have a shape different from that of the second emission region LA20 of the second pixel PX2. For example, the second emission region LA2 of the first pixel PX1 may have a rectangular shape, and the second emission region LA20 of the second pixel PX2 may have a triangular shape.

In addition, according to an embodiment of the present disclosure, the third emission region LA3 of the first pixel PX1 may have a shape different from that of the third emission region LA30 of the second pixel PX2. For example, the third emission region LA3 of the first pixel PX1 may have a rectangular shape, and the third emission region LA30 of the second pixel PX2 may have a triangular shape.

The second emission region LA20 of the second pixel PX2 may have a first triangular shape, and the third emission region LA30 of the second pixel PX2 may have a second triangular shape. As shown in FIGS. 2A and 2B, the first triangular shape and the second triangular shape may be the same as each other but may have different areas from each other. The present disclosure, however, is not limited thereto, and the first triangular shape and the second triangular shape may have different areas from each other and may be different from each other.

The first triangular shape may be line-symmetric about a direction parallel to the first direction DR1, and the second triangular shape may be line-symmetric about a direction parallel to the first direction DR1.

According to an embodiment of the present disclosure, the first emission region LA10 of the second pixel PX2 may have a rectangular shape. In such an embodiment, the rectangular shape of the first emission region LA10 may have one side that extends in the same direction as that of one side of the first triangular shape. In addition, one side of the second triangular shape may extend in the same direction as that of one side of the rectangular shape of the first emission region LA10.

For example, one side of the rectangular shape of the first emission region LA10 may extend in the first direction DR1, and one side of the first triangular shape and one side of the second triangular shape may extend in the first direction DR1. Alternatively, one side of the rectangular shape of the first emission region LA10 may extend in a direction different from the first direction DR1, and one side of the first triangular shape and one side of the second triangular shape may extend in a direction different from the first direction DR1.

The first triangular shape may be an isosceles triangular shape that is symmetric about a direction parallel to the first direction DR1, and the second triangular shape may be an isosceles triangular shape that is symmetric about a direction parallel to the first direction DR1. Although it is illustrated that the first triangular shape and the second triangular shape are isosceles triangular shapes that are symmetric about a direction parallel to the first direction DR1, the first triangular shape and the second triangular shape may have an isosceles triangular shape that is symmetric about a direction different from the first direction DR1, and the present disclosure is not limited to a particular embodiment.

The second emission regions LA20 of a plurality of second pixels PX2 may have the same first triangular shape, and the third emission regions LA30 of a plurality of second pixels PX2 may have the same second triangular shape. As discussed above, emission regions of pixels may be the same in terms of shape and arrangement. Thus, as illustrated in FIG. 2B, the second emission region LA20 of the second pixel PX2 in a second row may have the same first triangular shape as that of the second emission region LA20 of the second pixel PX2 in a first row and may be disposed at a position that corresponds to that of the second emission region LA20 of the second pixel PX2 in the first row. Similarly, the third emission region LA30 of the second pixel PX2 in the second row may have the same second triangular shape as that of the third emission region LA30 of the second pixel PX2 in the first row and may be disposed at a position that corresponds to that of the third emission region LA30 of the second pixel PX2 in the first row.

A center LA1-C of the first emission region LA1 of the first pixel PX1 and a center LA10-C of the first emission region LA10 of the second pixel PX2 may be aligned along an alignment line AL1 in the first direction DR1, but the present disclosure is not limited thereto. For example, a center of an emission region may be defined at a position at the same distance to each of vertices of the emission region or at the same minimum distance from each of corners of the emission region or may correspond to either a midpoint or centroid of a shape of the emission region.

Similarly, in a first row (or in the same row), a center of the second emission region LA2 of the first pixel PX1 and a center of the second emission region LA20 of the second pixel PX2 may be aligned in the first direction DR1. In addition, a center of the third emission region LA3 of the first pixel PX1 and a center of the third emission region LA30 of the second pixel PX2 may be aligned in the first direction DR1. FIGS. 2A and 2B show an example of an arrangement relationship between the first, second, and third emission regions LA1, LA2, LA3, LA10, LA20, and LA30 in which all of the first, second, and third emission regions LA1, LA2, LA3, LA10, LA20, and LA30 may be aligned, but in other embodiments, some of the first, second, and third emission regions LA1, LA2, LA3, LA10, LA20, and LA30 may not be aligned, and the present disclosure is not limited to a particular embodiment.

Because corresponding emission regions of the first pixel PX1 and the second pixel PX2 are have their centers aligned in the first direction DR1, it may be possible to reduce or prevent failure of recognition between the corresponding emission regions of the first pixel PX1 and the second pixel PX2 in the first direction DR1.

The first emission regions LA1 and LA10, the second emission regions LA2 and LA20, and the third emission regions LA3 and LA30 may have different areas from each other. For example, in FIG. 2B, an embodiment in which the first emission regions LA1 and LA10 have an area greater than that of any other emission region is illustrated, but the present disclosure is not limited thereto. Moreover, emission regions may have the same emission area.

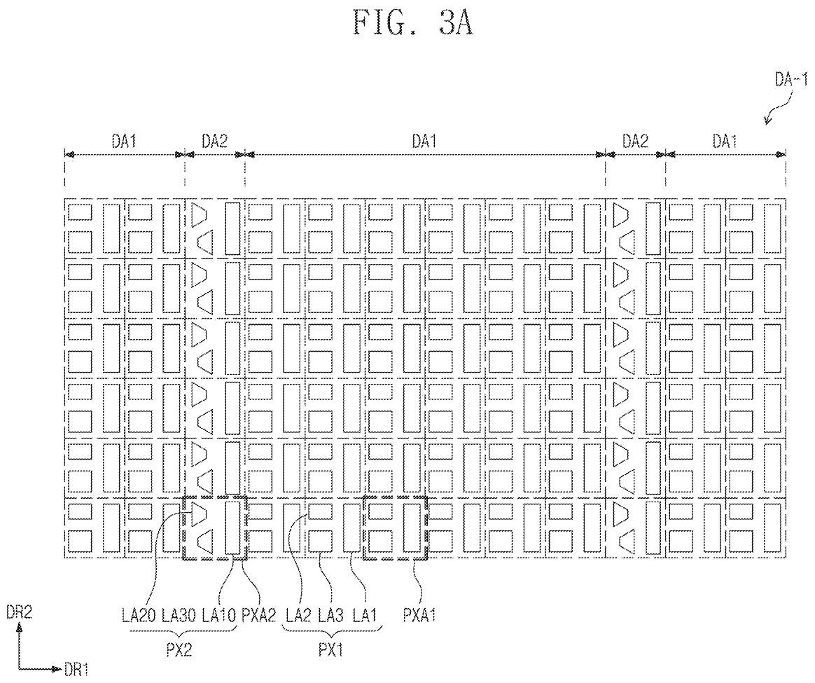

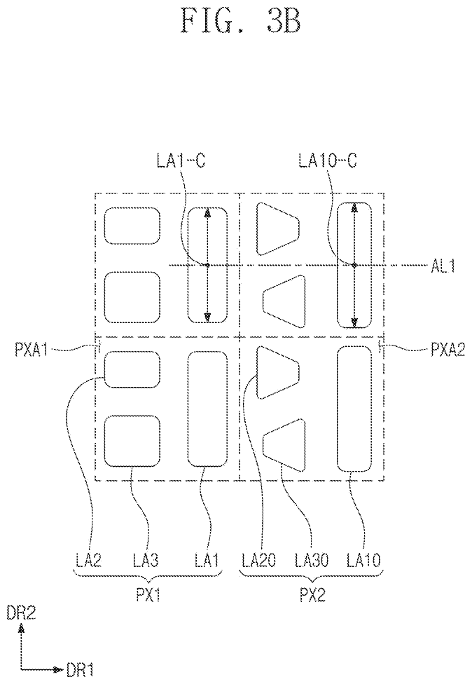

FIG. 3A is an enlarged plan view of a portion of a display panel according to an embodiment of the present disclosure. FIG. 3B is a plan view of a first pixel region and a second pixel region according to an embodiment of the present disclosure. For example, FIG. 3A is an enlarged plan view of the section AA depicted in FIG. 1 according to another embodiment, and FIG. 3B is a plan view of the first pixel region PXA1 and the second pixel region PXA2 depicted in FIG. 3A.

In explaining FIGS. 3A and 3B, the same reference numerals will be allocated to the same components as those discussed in FIGS. 2A and 2B, and a detailed description of the same components will be omitted.

Referring to FIGS. 3A and 3B, the second emission region LA20 of the second pixel PX2 and the third emission region LA30 of the second pixel PX2 may each have a polygonal shape other than a triangular shape.

According to an embodiment of the present disclosure, the first emission region LA10 of the second pixel PX2 may have a rectangular shape, the second emission region LA20 of the second pixel PX2 may have a first polygonal shape, and the third emission region LA30 of the second pixel PX2 may have a second polygonal shape. As shown in FIGS. 3A and 3B, the first polygonal shape and the second polygonal shape may be line-symmetric about a direction parallel to the second direction DR2. For example, the first polygonal shape may be obtained by rotating the second polygonal shape about 180 degrees and may have the same area as that of the second polygonal shape.

The present disclosure, however, is not limited thereto, and the first polygonal shape and the second polygonal shape may be non-line-symmetric and may have different areas from each other. In addition, the first polygonal shape and the second polygonal shape may have different polygonal shapes from each other, and the present disclosure is not limited to a particular embodiment. The second emission region LA2 or the third emission region LA3 of the first pixel PX1 may have a similar shape to and the same area as that of the second emission region LA20 or the third emission region LA30 of the second pixel PX2. Accordingly, it may be possible to reduce or prevent failure of recognition between corresponding emission regions of the first pixel PX1 and the second pixel PX2.

As shown in FIGS. 3A and 3B, the first polygonal shape and the second polygonal shape may have a first trapezoidal shape and a second trapezoidal shape, respectively. In another embodiment, the first polygonal shape and the second polygonal shape may each have a pentagonal shape, but the present disclosure is not limited to a particular embodiment.

As shown in FIGS. 3A and 3B, one side of the first trapezoidal shape may extend in the second direction DR2 that is the same as one side of the rectangular shape, and one side of the second trapezoidal shape may extend in the second direction DR2. In another embodiment, one side of each of the first and second trapezoidal shapes may extend in a direction different from the second direction DR2, but the present disclosure is not limited to a particular embodiment.

The second emission regions LA20 of a plurality of second pixels PX2 may have the same first polygonal shape, and the third emission regions LA30 of a plurality of second pixels PX2 may have the same second polygonal shape.

A plurality of first polygonal shapes may be line-symmetric about a direction parallel to the first direction DR1. In addition, a plurality of second polygonal shapes may be line-symmetric about a direction parallel to the first direction DR1.

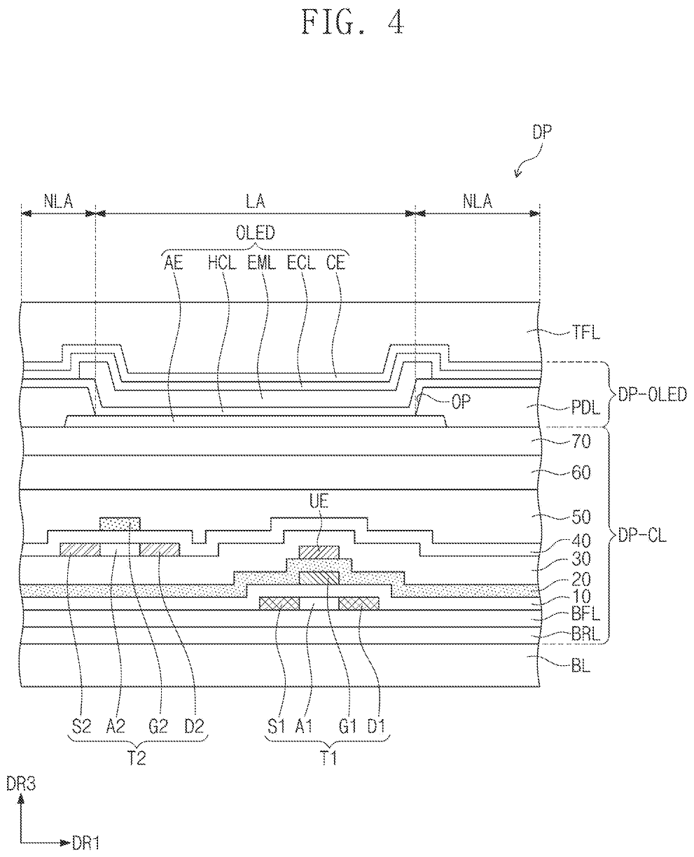

FIG. 4 is a cross-sectional view of a display panel according to an embodiment of the present disclosure. For example, FIG. 4 depicts a cross-section of one emission region LA. The emission region LA may correspond to each of the emission regions (see, e.g., LA1, LA2, LA3, LA10, LA20, and LA30 in FIG. 2A or 3A).

Referring to FIG. 4, a display panel DP may include a base layer BL, a circuit element layer DP-CL disposed on the base layer BL, a display element layer DP-OLED disposed on the circuit element layer DP-CL, and an upper dielectric layer TFL disposed on the display element layer DP-OLED.

The base layer BL may provide (or may be) a base surface on which the circuit element layer DP-CL is disposed. The base layer BL may be a rigid substrate or a flexible substrate that can be bent, folded, or rolled. The base layer BL may be a glass substrate, a metal substrate, or a polymer substrate. The present disclosure, however, is not limited thereto, and the base layer BL may be an inorganic layer, an organic layer, or a composite material layer.

The base layer BL may have a multi-layered structure. For example, the base layer BL may include a first synthetic resin layer, multiple or a single inorganic layer, and a second synthetic resin layer disposed on the multiple or single inorganic layer. Each of the first and second synthetic resin layers may include a polyimide-based resin, but the present disclosure is not limited thereto.

Each of the first and second synthetic resin layers may include a polyimide-based resin. Additionally or alternatively, each of the first and second synthetic resin layers may include at least one selected from an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In this description, the language a/an “X-based resin” refers to a resin including a functional group of X.

A synthetic resin layer may be formed on a support substrate used in fabricating the display panel DP. A conductive and a dielectric layer may be formed on the synthetic resin layer to form the circuit element layer DP-CL. When the support substrate is removed, the synthetic resin layer may correspond to the base layer BL.

The circuit element layer DP-CL may include at least one dielectric layer and a circuit element. The circuit element includes a signal line, a pixel driver circuit, and the like. The circuit element layer DP-CL may be formed by formation processes in which dielectric, semiconductor, and conductive layers are coated or deposited, and by patterning processes in which a photolithography process is used to pattern the dielectric, semiconductor, and conductive layers.

In an embodiment of the present disclosure, the circuit element layer DP-CL may include a buffer layer BFL, a barrier layer BRL, and a plurality of dielectric layers 10 to 70. In the illustrated embodiment, the dielectric layers 10 to 70 are shown as including first to seventh dielectric layers, but the number of the dielectric layer may be greater or less than seven. The barrier layer BRL, the buffer layer BFL, and the first to seventh dielectric layers 10 to 70 may include one of inorganic and organic layers. The barrier layer BRL and the buffer layer BFL may include an inorganic layer. At least one of the fifth to seventh dielectric layers 50 to 70 may include an organic layer.

FIG. 4 depicts, by way of example, an arrangement relationship of a first active A1, a second active A2, a first gate G1, a second gate G2, a first source S1, a second source S2, a first drain D1, and a second drain D2 included in first and second transistors T1 and T2. In the illustrated embodiment, the first active A1 and the second active A2 may include different materials from each other. The first active A1 may include a polysilicon semiconductor, and the second active A2 may include a metal oxide semiconductor. The first source S1 and the first drain D1 may each be a region having a doping concentration that is greater than that of the first active A1 and which acts as an electrode. The second source S2 and the second drain D2 may each be a region where a metal oxide semiconductor is reduced and which acts as an electrode.

In an embodiment of the present disclosure, the first active A1 and the second active A2 may include the same semiconductor material, and in such an embodiment, the circuit element layer DP-CL may have a simple stack structure.

The display element layer DP-OLED may include a pixel definition layer PDL and an emission element OLED. The emission element OLED may be an organic light-emitting diode or a quantum-dot light-emitting diode. A first electrode AE may be disposed on the seventh dielectric layer 70. An opening OP in the pixel definition layer PDL may expose at least a portion of the first electrode AE. The opening OP in the pixel definition layer PDL may define the emission region LA. Placement of (or arrangement of) the emission region LA may represent that of the first electrode AE. A non-emission region NLA may surround (e.g., may surround a periphery of) the emission region LA.

A hole control layer HCL and an electron control layer ECL may be disposed in common in the emission region LA and the non-emission region NLA. An emission layer EML may be provided in the form of a pattern to correspond to the opening OP. The emission layer EML may be deposited in a different manner from that of the hole control layer HCL and the electron control layer ECL, each of which is deposited like a film (e.g., as a common film). A mask assembly may be used to form the emission layer EML having a certain shape (or pattern).

Even when a misalignment causes the emission layer EML to be deposited and shifted from a target location, a large process margin may cause the emission layer EML to be deposited in only the non-emission region NLA and to prevent it from being deposited in the emission region LA. In addition, a large process margin may permit a mask to be designed to deposit the emission layer EML wider than the emission region LA, and thus, even in the occurrence of misalignment, the emission layer EML may be deposited such that it sufficiently covers a targeted emission region LA.

An open mask may be used such that the hole control layer HCL and the electron control layer ECL are formed in common on a plurality of pixels. A mask, called a fine metal mask (FMM), may be used such that the emission layer EML is differently formed according to the emission region LA.

The upper dielectric layer TFL may be disposed on the emission element OLED. The upper dielectric layer TFL may include a plurality of thin films. The plurality of thin films may include an inorganic layer and an organic layer. The upper dielectric layer TFL may include a dielectric layer for encapsulating the display element layer DP-OLED and a dielectric layer for increasing efficiency of light emission.

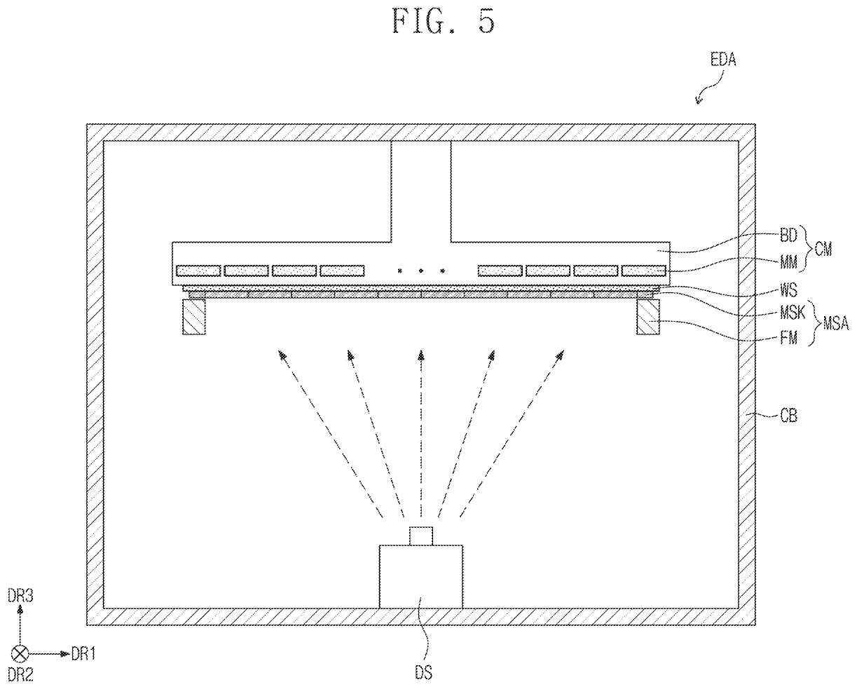

FIG. 5 is a cross-sectional view of a deposition apparatus according to an embodiment of the present disclosure.

Referring to FIG. 5, a deposition apparatus EDA according to an embodiment of the present disclosure may be used in a deposition process to form the emission layer EML shown in FIG. 4.

As illustrated in FIG. 5, the deposition apparatus EDA according to an embodiment of the present disclosure may include a deposition chamber CB, a fixing member CM, a deposition source DS disposed inside the deposition chamber CB, and a mask assembly MSA disposed inside the deposition chamber CB. The deposition apparatus EDA may further include one or more additional machines for providing an in-line system.

A vacuum may be established as a deposition condition in the deposition chamber CB. The deposition chamber CB may have a bottom surface, a ceiling surface, and sidewalls. The bottom surface of the deposition chamber CB may be parallel to a plane defined by a first direction DR1 and a second direction DR2. A third direction DR3 may be parallel to a normal direction to the bottom surface of the deposition chamber CB.

The fixing member CM may be disposed inside the deposition chamber CB and on (or over) the deposition source DS, and the mask assembly MSA may be fixed by the fixing member CM. The fixing member CM may be installed on the ceiling surface of the deposition chamber CB. The fixing member CM may include a jig or a robot arm that holds the mask assembly MSA.

The fixing member CM may include a body part BD and magnets MM combined with the body part BD. The body part BD may include a plate as a basic structure for fixing the mask assembly MSA, but the present disclosure is not limited thereto. The magnets MM may be disposed inside or outside the body part BD and are not limited to any one position. The magnets MM may fix the mask assembly MSA by magnetic force.

The deposition source DS may evaporate a deposition material, such as a light-emitting material, to spray the evaporated deposition material as a deposition vapor. The related deposition vapor may pass through the mask assembly MSA to be deposited in a pattern on a work substrate WS. The work substrate WS may be defined as a substrate in the middle of (or during) a procedure for fabricating the display panel DP described with reference to FIGS. 1 to 4, above. The work substrate WS may be in a state before the emission layer EML is formed for the purpose of fabricating the display panel DP depicted in FIG. 4. For example, the work substrate WS may include the base layer (see, e.g., BL of FIG. 4), the circuit element layer (see, e.g., DP-CL of FIG. 4), the first electrode (see, e.g., AF of FIG. 4), the pixel definition layer (see, e.g., PDL of FIG. 4), and the hole control layer (see, e.g., HCL of FIG. 4). Afterwards, an organic material may be provided from the deposition source DS through the mask assembly MSA to be patterned in the opening (see, e.g., OP of FIG. 4), thereby forming the emission layer (see, e.g., EML of FIG. 4).

The mask assembly MSA may be disposed inside the deposition chamber CB and on the deposition source DS, and the work substrate WS may be supported by the mask assembly MSA. The work substrate WS may include a glass substrate or a plastic substrate, but the present disclosure is not limited to a particular embodiment. The work substrate WS may include a polymer layer disposed on a base substrate. The base substrate may be removed in the latter stage of a process for fabricating the display panel (see, e.g., DP of FIG. 4), and the polymer layer may correspond to the base layer BL shown in FIG. 4.

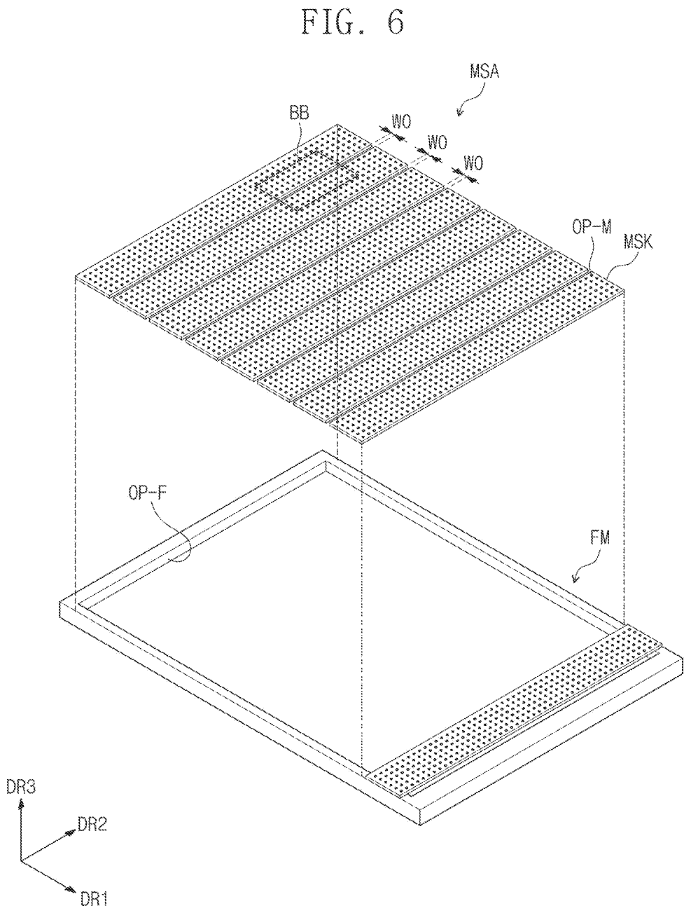

FIG. 6 is a perspective view of a mask assembly according to an embodiment of the present disclosure.

Referring to FIG. 6, the mask assembly MSA, according to an embodiment of the present disclosure, may include a frame FM and a plurality of masks MSK.

A frame opening OP-F may be defined inside the frame FM. The frame FM may have a rectangular shape in a plan view. A shape of the frame FM is not limited as long as the shape can support a plurality of masks MSK.

In an embodiment of the present disclosure, the frame FM is illustrated as having a single frame opening OP-F. The present disclosure, however, is not limited thereto, and the frame FM may include a plurality of openings OP-F. In such an embodiment, a plurality of masks MSK may be disposed on (or over) each frame opening OP-F. The work substrate (see, e.g., WS of FIG. 5) may include a plurality of unit regions, and the plurality of unit regions may respectively correspond to the plurality of openings OP-F. The display panel (see, e.g., DP of FIG. 4) may be formed at each of the plurality of unit regions. In the latter stage of fabrication process, the work substrate (see, e.g., WS of FIG. 5) may be divided into a plurality of display panels DP that correspond to the unit regions.

The frame FM may be formed of a metallic material. For example, the frame FM may include nickel (Ni), a nickel-cobalt (Ni—Co) alloy, or a nickel-iron (Ni—Fe) alloy.

The masks MSK may be disposed on the frame FM. The masks MSK may be welded and coupled to the frame FM. This, however, is an example, and when as long a certain coupling method can combine the masks MSK with the frame FM, the certain coupling method may be variously changed without being limited to a particular embodiment.

The masks MSK may extend in (e.g., may primarily extend in) a second direction DR2 and may be arranged in a first direction DR1. The masks MSK may include Invar (an alloy containing 64% iron (Fe) and 36% nickel (Ni)) having a low coefficient of thermal expansion but, alternatively, may include nickel (Ni), a nickel-cobalt alloy, or a different nickel-iron alloy.

A plurality of openings OP-M may be defined in each of the masks MSK. An organic material provided from the deposition source (see, e.g., DS of FIG. 5) may pass through a plurality of openings OP-M to be deposited in a pattern on the work substrate WS.

When a single mask is provided corresponding to one frame opening OP-F, the mask may sag or deform due to an increase in size of the mask. The sagging or deformation of the mask may induce failure (e.g., misalignment) of a deposition pattern.

According to an embodiment of the present disclosure, a mask corresponding to one frame opening OP-F may be provided in the form of a plurality of separated (or separate) masks MSK, and thus, the mask MSK may sag or deform.

The masks MSK are adjacent to each other in the first direction DR1 and may be spaced apart at an interval W0 from each other. A subsequently described line-deposition region may be formed in the interval W0.

When the masks MSK are continuously disposed (e.g., when the interval W0 is zero), it may be difficult to form a uniform deposition pattern because a relatively wide non-deposition region is formed at a boundary region between the masks MSK. When non-opening regions of the masks MSK are reduced to decrease the boundary region between the masks MSK, the masks MSK may be easily deformed. Thus, there may be a limitation as to how much boundary region between the masks MSK can be reduced.

The deposition apparatus (see, e.g., EDA of FIG. 5) according to an embodiment of the present disclosure may include a plurality of mask assemblies MSA. The plurality of mask assemblies MSA may include the masks MSK having the openings OP-M arranged with different characteristics. The number of the mask assemblies MSA may be determined based on the number and type of targeted deposition patterns. The deposition apparatus EDA may be configured such that the plurality of mask assemblies MSA are used to perform a deposition process several times to form the display panel (see, e.g., DP of FIG. 1) having a plurality of emission regions (see, e.g., LA1, LA2, LA3, LA10, LA20, and LA30 in FIG. 2A).

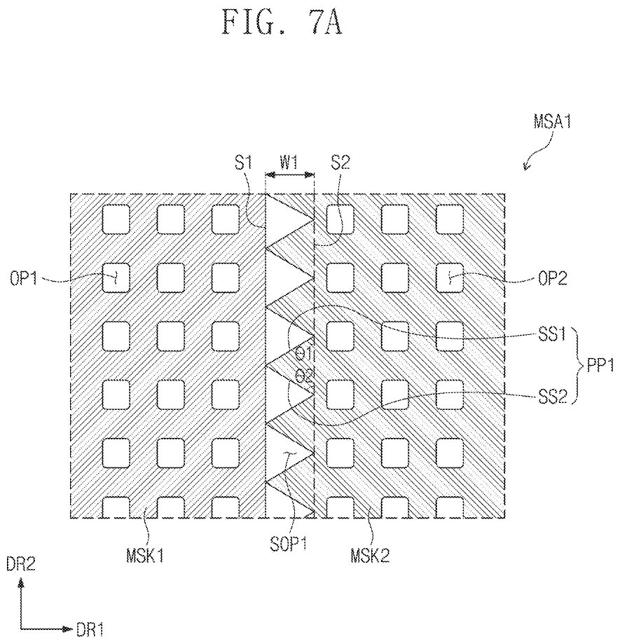

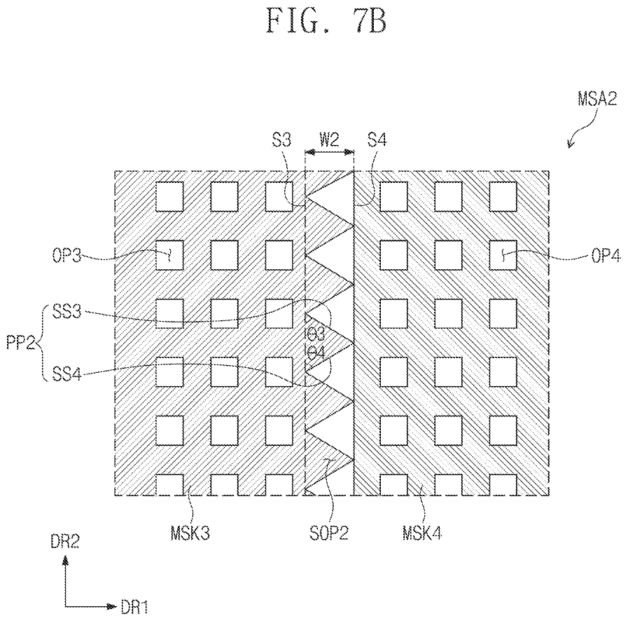

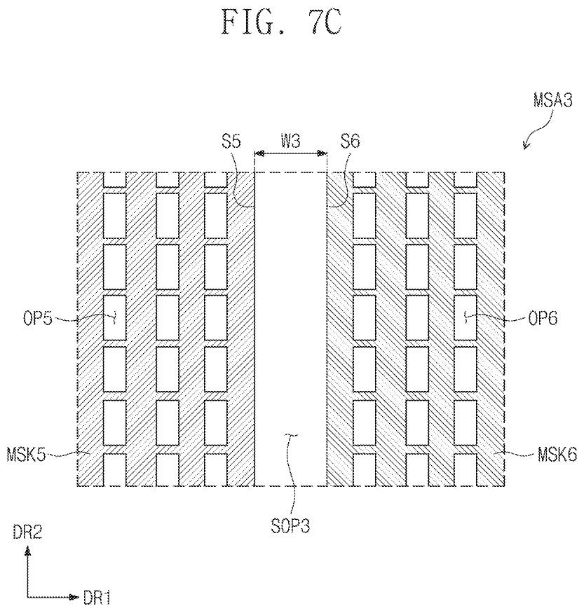

FIGS. 7A to 7C are plan views showing a portion BB of the mask assembly MSA in FIG. 6 according to embodiments of the present disclosure. For example, FIG. 7A is an enlarged plan view showing a portion of a first mask assembly according to an embodiment of the present disclosure. FIG. 7B is an enlarged plan view showing a portion of a second mask assembly according to an embodiment of the present disclosure. FIG. 7C is an enlarged plan view showing a portion of a third mask assembly according to an embodiment of the present disclosure.

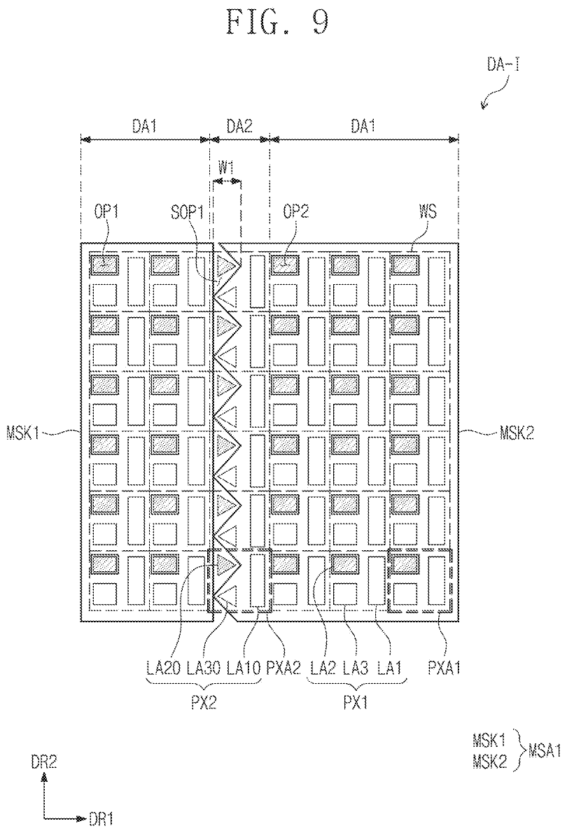

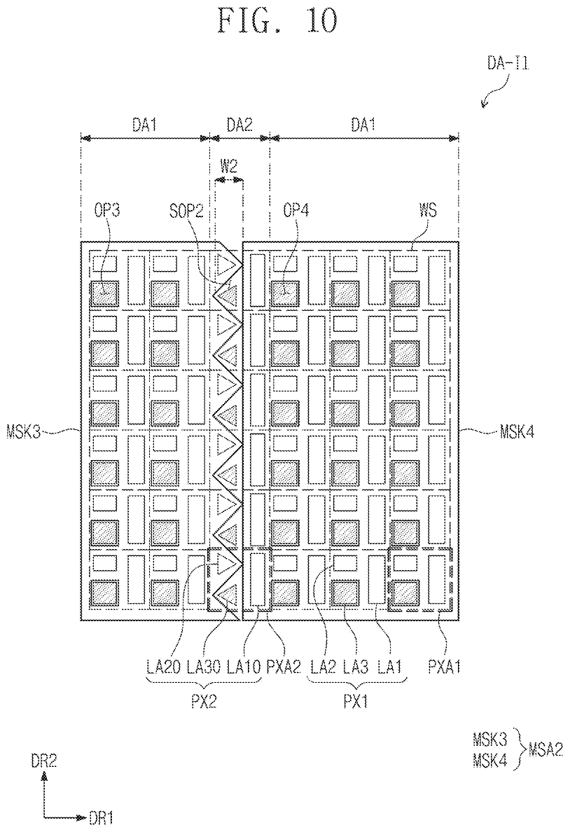

Referring to FIG. 7A, a first mask assembly MSA1 may overlap the work substrate (see, e.g., WS of FIG. 9) to deposit a light-emitting material on the second emission regions (see, e.g., LA2 and LA20 of FIG. 10) of the first pixel (see PX1 of FIG. 9) and the second pixel (see PX2 of FIG. 9).

The first mask assembly MSA1 may include a first mask MSK1 and a second mask MSK2. The first mask MSK1 and the second mask MSK2 may be disposed along (or may primarily extend in) the second direction DR2.

The first mask MSK1 may have a first opening OP1 defined to penetrate therethrough along a thickness direction of the first mask MSK1, and the second mask MSK2 may have a second opening OP2 defined to penetrate therethrough along a thickness direction of the second mask MSK2. As illustrated in FIG. 7A, the first opening OP1 and the second opening OP2 may have the same shape.

FIG. 7A shows that the first mask MSK1 and the second mask MSK2 have their lateral surfaces that face each other in the first direction DR1. A first lateral surface S1 of the first mask MSK1 may face a second lateral surface S2 of the second mask MSK2. The second lateral surface S2 may be an imaginary lateral surface.

The first lateral surface S1 of the first mask MSK1 may appear as a straight line that extends along the second direction DR2 in a plan view. When viewed in the first direction DR1, the first lateral surface S1 may be a wholly flat plane.

The second lateral surface S2 of the second mask MSK2 may extend along the second direction DR2 in a plan view and may have a plurality of first protrusions PP1 that protrude toward the first lateral surface S1. The first protrusions PP1 may protrude from the imaginary second lateral surface S2 toward the first lateral surface S1. The imaginary second lateral surface S2 may be a flat plane parallel to the first lateral surface S1.

The first protrusion PP1 may not overlap the first mask MSK1. For example, the first protrusion PP1 may be in contact with or spaced apart from the first lateral surface S1 of the first mask MSK1, but the present disclosure is not limited to a particular embodiment.

Each of the first protrusions PP1 may have a first inclined surface SS1 and a second inclined surface SS2. The first inclined surface SS1 may be oblique at a first angle θ1 with respect to the imaginary second lateral surface S2, and the second inclined surface SS2 may be oblique at a second angle θ2 with respect to the imaginary second lateral surface S2. The first inclined surface SS1 and the second inclined surface SS2 may have ends in contact with the imaginary second lateral surface S2. The first inclined surface SS1 and the second inclined surface SS2 may have their other end that are connected to each other. For example, in a plan view, the first inclined surface SS1, the second inclined surface SS2, and the imaginary second lateral surface S2 may be connected to constitute one triangular shape.

For example, the first angle θ1 and the second angle θ2 may be the same as each other. The first inclined surface SS1 and the second inclined surface SS2 may be line-symmetric about a direction parallel to the first direction DR1. In another embodiment, the first angle θ1 and the second angle θ2 may be different from each other, but the present disclosure is not limited to a particular embodiment.

Referring to FIG. 7A, the first protrusions PP1 may be connected along the second direction DR2. Therefore, one side of the second inclined surface SS2 of one second first protrusion PP1 may be connected to one end (or one side) of the first inclined surface SS1 of adjacent another first protrusion PP1.

A first sub-opening SOP1 may be defined by two neighboring first protrusions PP1 and the first lateral surface S1. The first sub-opening SOP1 may have a polygonal shape, such as a triangular shape as shown in figures, but the present disclosure is not limited to a particular embodiment. The first sub-opening SOP1 may have a shape different from that of the first opening OP1 and the second opening OP2.

According to an embodiment of the present disclosure, the masks MSK1 and MSK2 have lateral surfaces that are differently designed may be disposed adjacent to each other such that a space between the masks MSK1 and MSK2 has an opening (or the first sub-opening SOP1) that is formed for patterning an organic material. According to an embodiment of the present disclosure, the masks MSK1 and MSK2 may be provided with not only a typically shaped opening (e.g., the first opening OP1 and/or the second opening OP2) but also an atypically shaped opening (e.g., the first sub-opening SOP1). Therefore, because there is no requirement for an additional mask for deposition on a line-deposition region which will be discussed below, it may be possible to reduce process costs and to increase productivity.

Although not shown in figures, when opposite lateral surfaces of the second mask MSK2 correspondingly face the first masks MSK1, a plurality of first protrusions PP1 may be formed on each of the opposite lateral surfaces of the second mask MSK2.

For example, opposite lateral surfaces of the first mask MSK1 may correspond to opposite lateral surfaces of the second mask MSK2. Another lateral surface opposite to the first lateral surface S1 of the first mask MSK1 may be the same as the second lateral surface S2 of the second mask MSK2. In addition, another lateral surface opposite to the second lateral surface S2 of the second mask MSK2 may be the same as the first lateral surface S1 of the first mask MSK1.

Referring to FIG. 7B, in a deposition process, a second mask assembly MSA2 may be a component with which the first mask assembly (see, e.g., MSA1 of FIG. 7A) is replaced and which is provided on (or over) the work substrate (see, e.g., WS of FIG. 10), and the second mask assembly MSA2 and the first mask assembly MSA1 may correspond to components that are provided on the work substrate WS at different times. As discussed below in connection with FIG. 10, the second mask assembly MSA2 according to an embodiment of the present disclosure may be used in a deposition step in which a light-emitting material is provided to the third emission region LA3 of the first pixel PX1 and the third emission region LA30 of the second pixel PX2.

The second mask assembly MSA2 may include a third mask MSK3 and a fourth mask MSK4. The third mask MSK3 may have a third opening OP3 defined to penetrate therethrough along a thickness direction of the third mask MSK3, and the fourth mask MSK4 may have a fourth opening OP4 defined to penetrate therethrough along a thickness direction of the fourth mask MSK4. As illustrated in FIG. 7B, the third opening OP3 and the fourth opening OP4 may have the same shape. The shape of the third opening OP3 and the fourth opening OP4 may be different from that of the first opening OP1 and the second opening OP2, described above with respect to FIG. 7A. In addition, an area of the third opening OP3 and the fourth opening OP4 may be the same as or different from that of the first opening OP1 and the second opening OP2, but the present disclosure is not limited to a particular embodiment.

FIG. 7B shows that the third mask MSK3 and the fourth mask MSK4 have their lateral surfaces that face each other in the first direction DR1. A third lateral surface S3 of the third mask MSK3 may face a fourth lateral surface S4 of the fourth mask MSK4. The third lateral surface S3 may be an imaginary lateral surface.

The fourth lateral surface S4 of the fourth mask MSK4 may appear as a straight line that extends along the second direction DR2 in a plan view. When viewed in the first direction DR1, the fourth lateral surface S4 may appear as a wholly flat plane.

The third lateral surface S3 of the third mask MSK3 may extend along the second direction DR2 in a plan view and may have a plurality of second protrusions PP2 that protrude toward the fourth lateral surface S4. The second protrusions PP2 may protrude from the imaginary third lateral surface S3 toward the fourth lateral surface S4. The imaginary third lateral surface S3 may be a flat plane parallel to the fourth lateral surface S4.

The second protrusion PP2 and the first protrusion (see, e.g., PP1 of FIG. 7A) discussed above may have different shapes from each other or the same shape as each other, and the present disclosure is not limited to a particular embodiment.

The second protrusion PP2 may not overlap the fourth mask MSK4. For example, the second protrusion PP2 may be in contact with or spaced apart from the fourth lateral surface S4 of the fourth mask MSK4, and the present disclosure is not limited to a particular embodiment.

Each of the second protrusions PP2 may have a third inclined surface SS3 and a fourth inclined surface SS4. The third inclined surface SS3 may be oblique at a third angle θ3 with respect to the imaginary third lateral surface S3, and the fourth inclined surface SS4 may be oblique at a fourth angle θ4 with respect to the imaginary third lateral surface S3. The third inclined surface SS3 and the fourth inclined surface SS4 may have ends in contact with the imaginary third lateral surface S3. The third inclined surface SS3 and the fourth inclined surface SS4 may have other ends that are connected to each other. For example, in a plan view, the third inclined surface SS3, the fourth inclined surface SS4, and the imaginary third lateral surface S3 may be connected to constitute one triangular shape.

For example, the third angle θ3 and the fourth angle θ4 may be the same as each other. The third inclined surface SS3 and the fourth inclined surface SS4 may be line-symmetric about a direction parallel to the first direction DR1. In another embodiment, the third angle θ3 and the fourth angle θ4 may be different from each other, and the present disclosure is not limited to a particular embodiment.

A second sub-opening SOP2 may be defined by two neighboring second protrusions PP2 and the fourth lateral surface S4. The second sub-opening SOP2 may have a polygonal shape, such as a triangular shape as shown in FIG. 7B, but the present disclosure is not limited to a particular embodiment. The second sub-opening SOP2 may have a shape different from that of the third opening OP3 and the fourth opening OP4. In addition, the shape of the second sub-opening SOP2 may be different from that of the first sub-opening (see, e.g., SOP1 of FIG. 7A).

According to embodiments of the present disclosure, the masks MSK3 and MSK4 have lateral surfaces that are differently designed and may be disposed adjacent to each other such that a space between the masks MSK3 and MSK4 has an opening (or the second sub-opening SOP2) that is formed for patterning an organic material. Therefore, because there is no requirement for an additional mask for deposition on a line-deposition region, which will be discussed below, it may be possible to reduce process costs and to increase productivity.

When opposite lateral surfaces of the fourth mask MSK4 correspondingly face the third masks MSK3, a plurality of second protrusions PP2 may be formed on each of opposite lateral surfaces of the third mask MSK3.

For example, opposite lateral surfaces of the third mask MSK3 may correspond to opposite lateral surfaces of the fourth mask MSK4. Another lateral surface opposite to the third lateral surfaces S3 of the third mask MSK3 may be the same as the fourth lateral surface S4 of the fourth mask MSK4. In addition, another lateral surface opposite to the fourth lateral surface S4 of the fourth mask MSK4 may be the same as the third lateral surface S3 of the third mask MSK3.

In an embodiment of the present disclosure, the second mask assembly MSA2 is described as having a different shape from that of the first mask assembly (see, e.g., MSA1 of FIG. 7A), but the second mask assembly MSA2 may have the same shape as that of the first mask assembly MSA1. Even when the first and second mask assemblies MSA1 and MSA2 have the same shape, the second mask assembly MSA2 may replace the first mask assembly MSA1 and may be provided on (or over) the work substrate (see, e.g., WS of FIG. 10).

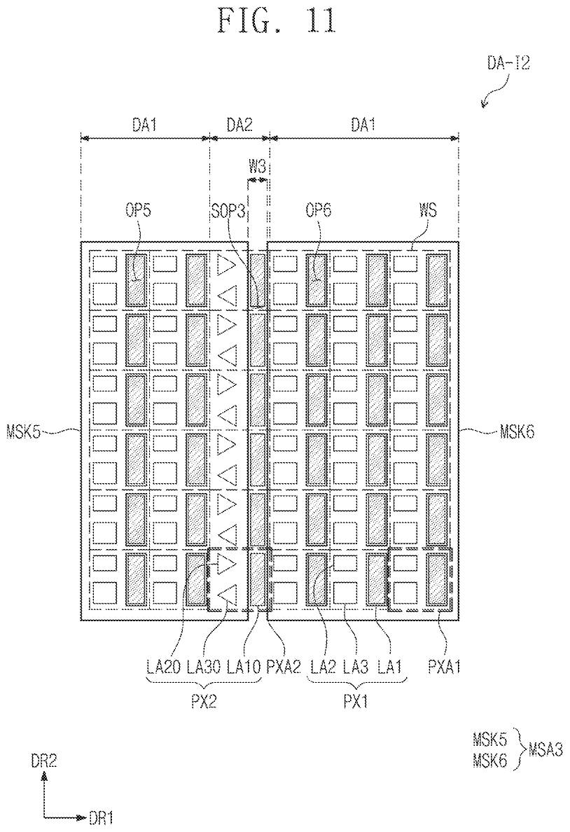

Referring to FIG. 7C, in a deposition process, a third mask assembly MSA3 may correspond to a component with which the first mask assembly (see, e.g., MSA1 of FIG. 7A) and the second mask assembly (see, e.g., MSA2 of FIG. 7B) are replaced and which is provided on (or over) the work substrate (see, e.g., WS of FIG. 11). As discussed below in connection with FIG. 11, the third mask assembly MSA3 according to an embodiment of the present disclosure may be used in a deposition step in which a light-emitting material is provided to the first emission region LA1 of the first pixel PX1 and the first emission region LA10 of the second pixel PX2.

The third mask assembly MSA3 may include a plurality of masks. The third mask assembly MSA3 may include a fifth mask MSK5 and a sixth mask MSK6. The fifth mask MSK5 may have a fifth opening OP5 defined to penetrate therethrough along a thickness direction of the fifth mask MSK5, and the sixth mask MSK6 may have a sixth opening OP6 defined to penetrate therethrough along a thickness direction of the sixth mask MSK6. As illustrated in FIG. 7C, the fifth opening OP5 and the sixth opening OP6 may have the same shape as each other. The shape of the fifth opening OP5 and the sixth opening OP6 may be different from that of the first opening OP1, described above with respect to FIG. 7A, or that of the third opening OP3, described above with respect to FIG. 7B.

The fifth mask MSK5 and the sixth mask MSK6 may be arranged spaced apart from each other in the first direction DR1. A third sub-opening SOP3 may be defined in a region between the fifth mask MSK5 and the sixth mask MSK6. The fifth mask MSK5 and the sixth mask MSK6 may be masks that are line-symmetric about the first direction DR1 and have the same shape, but the present disclosure is not limited thereto.

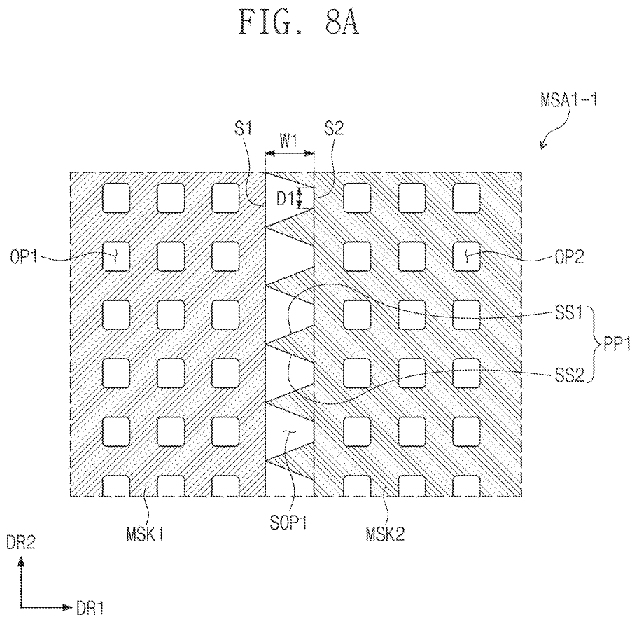

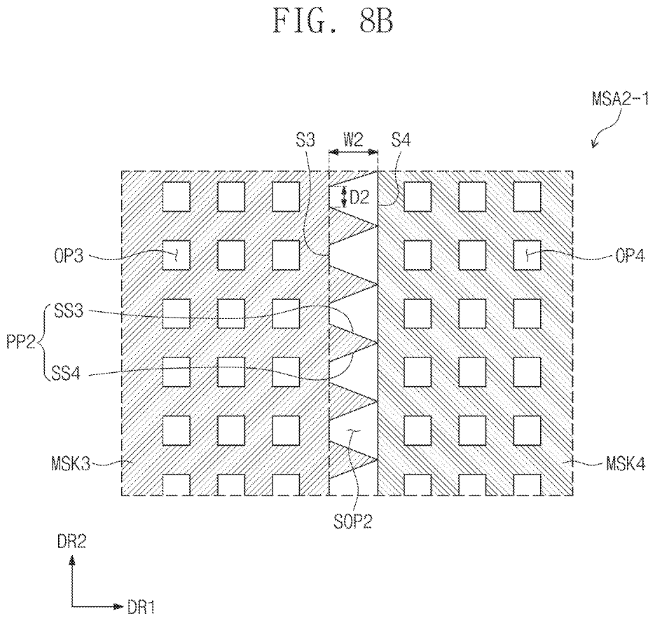

FIGS. 8A and 8B are plan views showing mask assemblies according to an embodiment of the present disclosure. For example, FIG. 8A is a plan view of a first mask assembly MSA1-1 according to an embodiment of the present disclosure, and FIG. 8B is a plan view of a second mask assembly MSA2-1 according to an embodiment of the present disclosure.

In describing FIGS. 8A and 8B, the same reference numerals will be allocated to the same components as those discussed in FIGS. 7A and 7B, and a detailed description of the same components will be omitted.

Referring to FIG. 8A, the first mask assembly MSA1-1 according to an embodiment of the present disclosure may have a plurality of first protrusions PP1 that are disposed spaced apart at an interval D1 in the second direction DR2.

A first sub-opening SOP1 may be defined by two neighboring first protrusions PP1, the first lateral surface S1, and the second lateral surface S2. The first sub-opening SOP1 may have a polygonal shape, such as a trapezoidal shape as shown in FIG. 8A, but the present disclosure is not limited to a particular embodiment. Because the first sub-opening SOP1 has a trapezoidal shape, the first sub-opening SOP1 may have a rectangular shape different from that of the first opening OP1 and the second opening OP2. Therefore, the second emission region LA2 or the third emission region LA3 of the first pixel PX1 may have a similar shape to that of the second emission region LA20 or the third emission region LA30 of the second pixel PX2, and accordingly, it may be possible to reduce or prevent failure of recognition between corresponding emission regions of the first pixel PX1 and the second pixel PX2 (see, e.g., FIG. 3B).

Referring to FIG. 8B, the second mask assembly MSA2-1 according to an embodiment of the present disclosure may have a plurality of second protrusions PP2 that are disposed spaced apart at an interval D2 in the second direction DR2.

A second sub-opening SOP2 may be defined by two neighboring second protrusions PP2, the third lateral surface S3, and the fourth lateral surface S4. The second sub-opening SOP2 may have a polygonal shape, such as a trapezoidal shape as shown in FIG. 8B, but the present disclosure is not limited to a particular embodiment. The second sub-opening SOP2 may have a rectangular shape different from that of the third opening OP3 and the fourth opening OP4, and therefore, in a subsequent deposition process, the first pixel PX1 and the second pixel PX2 may have emission regions whose shapes are similar to each other (see, e.g., FIG. 3B). Accordingly, it may be possible to prevent a reduction in recognition between neighboring pixels.

FIGS. 9 to 11 are plan views showing a state where mask assemblies overlap a work substrate according to an embodiment of the present disclosure. For example, FIG. 9 is a plan view showing a state in which a work substrate and a first mask assembly overlap each other. FIG. 10 is a plan view showing a state in which a work substrate and a second mask assembly overlap each other. FIG. 11 is a plan view showing a state in which a work substrate and a third mask assembly overlap each other. In FIGS. 9 to 11, emission regions to be formed by a different (e.g., an earlier or subsequent) mask assembly are indicated by solid lines, and emission regions formed by a current mask assembly are indicated by shading.

Referring to FIG. 9, a step in which a light-emitting material is deposited on the second emission region LA2 of the first pixel PX1 and the second emission region LA20 of the second pixel PX2 in a preliminary display region DA-I may be performed in a state where the first mask MSK1 and the second mask MSK2 of the first mask assembly MSA1 are aligned with the work substrate WS. The first mask MSK1 and the second mask MSK2 may be disposed spaced apart at a first interval W1 at (e.g., aligned with) the second display region DA2 of the work substrate WS. The first interval W1 may denote a maximum interval between the first mask MSK1 and the second mask MSK2.

The first mask MSK1 and the second mask MSK2 may overlap the first emission regions LA1 and the third emission regions LA3 of the first display region DA1. The first openings OP1 and the second openings OP2 may overlap the second emission regions LA2 of the first display region DA1. The first opening OP1 and the second opening OP2 may each have an area greater than that of the first emission region LA1.

A spacing region between the first mask MSK1 and the second mask MSK2 may overlap the second emission regions LA20 of the second display region DA2. The spacing region between the first mask MSK1 and the second mask MSK2 may correspond to the line-deposition region discussed above. In such an embodiment, the line-deposition region may overlap the first sub-opening SOP1.

A light-emitting material may be deposited on the first display region DA1 through the first opening OP1 and the second opening OP2, thereby forming the emission layer (see, e.g., EML of FIG. 4). In addition, the light-emitting material may be deposited on the second display region DA2 through the first sub-opening SOP1, thereby forming the emission layer (see, e.g., EML of FIG. 4). For example, the light-emitting material, which is deposited through the first mask assembly MSA1 on the first display region DA1 and the second display region DA2, may be a red light-emitting material. Alternatively, the light-emitting material may be a green light-emitting material or a blue light-emitting material, and the present disclosure is not limited to a particular embodiment.

Referring to FIG. 10, a step in which a light-emitting material is deposited on the third emission region LA3 of the first pixel PX1 and the third emission region LA30 of the second pixel PX2 in a preliminary display region DA-11 may be performed in a state where the third mask MSK3 and the fourth mask MSK4 of the second mask assembly MSA2 are aligned with the work substrate WS. The second mask assembly MSA2 may replace the first mask assembly (see, e.g., MSA1 of FIG. 9) and may be aligned with the work substrate WS, and the second mask assembly MSA2 and the first mask assembly MSA1 may be provided at different times.

The third mask MSK3 and the fourth mask MSK4 may be disposed spaced apart at a second interval W2 in (or aligned with) the second display region DA2 of the work substrate WS. The second interval W2 may denote a maximum interval between the third mask MSK3 and the fourth mask MSK4.

The third mask MSK3 and the fourth mask MSK4 may overlap the first emission regions LA1 and the second emission regions LA2 of the first display region DA1. The third openings OP3 and the fourth openings OP4 may overlap the third emission regions LA3 of the first display region DA1. The third opening OP3 and the fourth opening OP4 may each have an area greater than that of the third emission region LA3.

A spacing region between the third mask MSK3 and the fourth mask MSK4 may overlap the third emission regions LA30 of the second display region DA2. The spacing region between the third mask MSK3 and the fourth mask MSK4 may correspond to the line-deposition region discussed above. In such an embodiment, the line-deposition region may overlap the second sub-opening SOP2.

A light-emitting material may be deposited on the first display region DA1 through the third opening OP3 and the fourth opening OP4, thereby forming the emission layer (see, e.g., EML of FIG. 4). In addition, the light-emitting material may be deposited on the second display region DA2 through the second sub-opening SOP2, thereby forming the emission layer (see, e.g., EML of FIG. 4). For example, the light-emitting material, which is deposited through the second mask assembly MSA2 on the first display region DA1 and the second display region DA2, may be a green light-emitting material. Alternatively, the light-emitting material may be a red light-emitting material or a blue light-emitting material, and the present disclosure is not limited to a particular embodiment. The light-emitting material deposited on the display regions DA1 and DA2 through the second mask assembly MSA2 may be different from the light-emitting material deposited on the display regions DA1 and DA2 through the first mask assembly (see, e.g., MSA1 of FIG. 9).

Referring to FIG. 11, a step in which a light-emitting material is deposited on the first emission region LA1 of the first pixel PX1 and the first emission region LA10 of the second pixel PX2 in a preliminary display region DA-12 may be performed in a state where the fifth mask MSK5 and the sixth mask MSK6 of the third mask assembly MSA3 are aligned with the work substrate WS. The third mask assembly MSA3 may replace the first mask assembly (see, e.g., MSA1 of FIG. 9) and the second mask assembly (see, e.g., MSA2 of FIG. 10) and may be aligned with the work substrate WS.

The fifth mask MSK5 and the sixth mask MSK6 may be disposed spaced apart at a third interval W3 in (e.g., aligned with) the second display region DA2 of the work substrate WS.

The fifth mask MSK5 and the sixth mask MSK6 may overlap the second emission regions LA2 and the third emission regions LA3 of the first display region DA1. The fifth openings OP5 and the sixth openings OP6 may overlap the first emission regions LA1 of the first display region DA1. The fifth opening OP5 and the sixth opening OP6 may each have an area greater than that of the first emission region LA1.

A spacing region between the fifth mask MSK5 and the sixth mask MSK6 may overlap the first emission regions LA10 of the second display region DA2. The spacing region between the fifth mask MSK5 and the sixth mask MSK6 may correspond to the line-deposition region discussed above. In such an embodiment, the line-deposition region may overlap the third sub-opening SOP3.

A light-emitting material may be deposited on the first display region DA1 through the fifth opening OP5 and the sixth opening OP6, thereby forming the emission layer (see, e.g., EML of FIG. 4). In addition, the light-emitting material may be deposited on the second display region DA2 through the third sub-opening SOP3, thereby forming the emission layer (see, e.g., EML of FIG. 4). For example, the light-emitting material deposited through the third mask assembly MSA3 on the first display region DA1 and the second display region DA2 may be a blue light-emitting material, but the present disclosure is not limited thereto. The light-emitting material deposited on the display regions DA1 and DA2 through the third mask assembly MSA3 may be different from the light-emitting material deposited on the display regions DA1 and DA2 through the first mask assembly (see, e.g., MSA1 of FIG. 9) and the second mask assembly (see, e.g., MSA2 of FIG. 10).

After depositing light-emitting material and patterning the deposited light-emitting material, the first emission regions LA10 are spaced apart in the second direction DR2, separately. Before patterning, the first emission regions LA10 may be connected in the second direction DR2.

Referring together to FIGS. 9 to 11, when a light-emitting material is deposition on the display regions DA1 and DA2 through the first, second, and third mask assemblies MSA1, MSA2, and MSA3, one of the first, second, and third mask assemblies MSA1, MSA2, and MSA3 may be first used to deposit a light-emitting material on the display regions DA1 and DA2. For example, the first mask assembly MSA1 may be first used to deposit a light-emitting material in the display regions DA1 and DA2, and in such an embodiment, a deposition sequence is not limited to a specific sequence.

A display panel according to an embodiment of the present disclosure may prevent the occurrence of a difference in recognition between neighboring pixel regions.

A deposition apparatus according to an embodiment of the present disclosure may fabricate a display panel capable of preventing the occurrence of a difference in recognition between neighboring pixel regions.

A deposition apparatus according to an embodiment of the present disclosure may be configured such that a plurality of mask assemblies, each including a plurality of masks, is used to fabricate a medium-sized or large-sized display panel without defects.

A deposition apparatus according to an embodiment of the present disclosure may be configured such that neighboring masks are spaced apart from each other to prevent deposition errors in a boundary region therebetween.

Although the present disclosure has been described with reference to a number of embodiments thereof, it will be understood by those of ordinary skill in the art that various changes in form and details may be made without departing from the spirit and scope of the present disclosure as set forth in the following claims and their equivalents. Thus, the scope of the present disclosure is not limited by the embodiments and examples described above, but by the following claims and their equivalents.

What is claimed is:

1. A display panel comprising:
a plurality of first display regions arranged along a first direction;
a second display region between the first display regions;
a first pixel in each of the first display regions; and
a second pixel in the second display region, each of the first pixel and the second pixel comprising:
a first color emission element;
a second color emission element spaced apart from the first color emission element in the first direction; and
a third color emission element spaced apart from the first color emission element in the first direction and from the second color emission element in a second direction, the second direction crossing the first direction,
wherein a shape of an emission region of the second color emission element in the first pixel is different from a shape of an emission region of the second color emission element in the second pixel.

2. The display panel of claim 1, wherein a shape of an emission region of the third color emission element in the first pixel is different from a shape of an emission region of the third color emission element in the second pixel.

3. The display panel of claim 1, wherein a shape of an emission region of the first color emission element in the first pixel is different from a shape of an emission region of the first color emission element in the second pixel.

4. The display panel of claim 3, wherein an area of the emission region of the first color emission element in the first pixel is substantially the same as an area of the emission region of the first color emission element in the second pixel.

5. The display panel of claim 1, wherein each of the first pixel and the second pixel is provided in plural, and
wherein the second color emission elements of the second pixels and the third color emission elements of the second pixels are alternately arranged along the second direction.

6. The display panel of claim 5, wherein the second color emission elements of the first pixels and the third color emission elements of the first pixels are alternately arranged along the second direction.

7. The display panel of claim 1, wherein the first pixel and the second pixel are aligned along the first direction or the second direction.

8. The display panel of claim 1, wherein the emission region of the second color emission element in the second pixel has a first triangular shape in a plan view, the first triangular shape being line-symmetric about a direction parallel to the first direction, and
wherein an emission region of the third color emission element in the second pixel has a second triangular shape in a plan view, the second triangular shape being line-symmetric about the direction parallel to the first direction.

9. The display panel of claim 8, wherein an emission region of the first color emission element in the second pixel has a rectangular shape in a plan view,
wherein one side of the first triangular shape and one end of the second triangular shape face one side of the rectangular shape, and
wherein the one side of the first triangular shape and one side of the second triangular shape extend in the same direction.

10. The display panel of claim 8, wherein each of the first pixel and the second pixel is provided in plural,
wherein the first triangular shapes of neighboring ones of the second pixels are line-symmetric about the direction parallel to the first direction, and
wherein the second triangular shapes of neighboring ones of the second pixels are line-symmetric about the direction parallel to the first direction.

11. The display panel of claim 1, wherein each of the first pixel and the second pixel is provided in plural,
wherein the emission region of the second color emission element in each of the second pixels has a first polygonal shape in a plan view,
wherein an emission region of the third color emission element in each of the first pixels has a second polygonal shape in a plan view,
wherein the first polygonal shape of each of the second pixels is line-symmetric about a direction parallel to the first direction, and
wherein the second polygonal shape of each of the first pixels is line-symmetric about the direction parallel to the first direction.

12. The display panel of claim 11, wherein emission regions of the first, second, and third color emission elements have different areas from each other.

13. The display panel of claim 1, wherein a width of each of the first display regions in the first direction is greater than a width of the second display region in the first direction.

14. A deposition apparatus comprising:
a deposition source configured to provide a substrate with a deposition material; and
a plurality of mask assemblies between the deposition source and the substrate,
wherein the plurality of mask assemblies comprises a first mask assembly comprising:
a first frame having a first frame opening that penetrates the first frame along a thickness direction of the first frame;
a first mask connected to the first frame and having a plurality of first openings, each of which overlaps the first frame opening in a plan view; and
a second mask connected to the first frame and spaced apart from the first mask in a first direction and having a plurality of second openings, each of which overlaps the first frame opening in a plan view and has the same shape as the first opening, and
wherein a plurality of first sub-openings are defined between the first mask and the second mask, the first sub-opening having a shape different from the shape of the first opening and the second opening.

15. The deposition apparatus of claim 14, wherein the plurality of mask assemblies further comprises a second mask assembly comprising:
a second frame having a second frame opening that penetrates the second frame along a thickness direction of the second frame;
a third mask connected to the second frame and having a plurality of third openings, each of which overlaps the second frame opening in a plan view; and
a fourth mask connected to the second frame and spaced apart from the third mask in the first direction and having a plurality of fourth openings, each of which overlaps the second frame opening in a plan view,
wherein the second mask assembly is configured to replace the first mask assembly on the substrate, and
wherein a plurality of second sub-openings are defined between the third mask and the fourth mask, the second sub-opening having a shape different from the third opening and the fourth opening.

16. The deposition apparatus of claim 15, wherein the first mask has a first surface that extends along a second direction crossing the first direction,
wherein the second mask has a second surface that extends along the second direction and faces the first surface and a plurality of first protrusions protruding from the second surface toward the first mask, and
wherein the first sub-openings are defined between the first protrusions and the first surface.

17. The deposition apparatus of claim 16, wherein the first protrusion has a first inclined surface that is oblique at a first angle with respect to the second surface and a second inclined surface that is oblique at a second angle with respect to the first surface.

18. The deposition apparatus of claim 17, wherein the first angle and the second angle are the same.

19. The deposition apparatus of claim 16, wherein the third mask has a third surface that extends along the second direction and a plurality of second protrusions protruding from the third surface toward the fourth mask,
wherein the fourth mask has a fourth surface that extends along the second direction and faces the third surface, and
wherein the second sub-openings are defined between the second protrusions and the third surface.

20. The deposition apparatus of claim 19, wherein the plurality of first protrusions are spaced apart from each other at a first interval along the second direction, and
wherein the plurality of second protrusions are spaced apart from each other at a second interval along the second direction.
